(19) United States
(12) Patent Application Publication
(10) Pub. No.: US 2026/0157136 A1
(43) Pub. Date: Jun. 4, 2026

(54) SEMICONDUCTOR WAFER AND METHOD FOR MANUFACTURING SEMICONDUCTOR WAFER

(71) Applicant: NGK INSULATORS, LTD., Nagoya-shi (JP)

(72) Inventors: Jun YOSHIKAWA, Nagoya-shi (JP); Kiyoshi MATSUSHIMA, Nagoya -shi (JP); Takashi YOSHINO, Ama-shi (JP)

(21) Appl. No.: 19/464,731

(22) Filed: Jan. 30, 2026

Related U.S. Application Data
(63) Continuation of application No. PCT/JP2024/016613, filed on Apr. 26, 2024.

(30) Foreign Application Priority Data
Sep. 22, 2023 (WO) PCT/JP2023/034602

(51) Int. Cl. H10P 54/30; H10D 62/832; H10D 62/834; H10P 14/20

(52) U.S. Cl. CPC H10P 54/30; H10P 14/3408; H10P 14/36; H10D 62/8325; H10D 62/834

(57) ABSTRACT

A semiconductor wafer containing SiC as a main component has: a first main surface; a second main surface opposite the first main surface; and a release-promoting layer formed between the first main surface and the second main surface within the range of 10 μm or less in a thickness direction perpendicular to the first main surface and the second main surface, wherein the release-promoting layer is an area where voids or a release-promoting substance is distributed at an interval of 200 μm or less throughout the range of 500 μm or more in a plane direction in parallel with the first main surface and the second main surface.

### CROSS-REFERENCE TO RELATED APPLICATION

This application is a continuation application of PCT/JP2024/016613 filed on Apr. 26, 2024, which claims the benefit of priority of International Patent Application No. PCT/JP2023/034602 filed on Sep. 22, 2023, the entire contents of which are incorporated herein by reference.

### 1. Technical Field

The present invention relates to a semiconductor wafer and a method for manufacturing the semiconductor wafer.

### 2. Description of Related Art

Conventionally, there is known a technique that forms a device (for example, electrodes and wiring patterns) on a surface of a semiconductor wafer and then forms a modified layer inside the semiconductor wafer in its plane direction by applying a laser light to a focal position at a specified depth in a thickness direction of the semiconductor wafer, and divides the semiconductor wafer, at this modified layer as a starting point, into a device-formed part and a no-device-formed part (for example, PTL 1: Japanese Patent Application Laid-Open (Kokai) Publication No. 2023-73458).

For example, if the modified layer inside the semiconductor wafer is not formed sufficiently by the method of PTL 1 and when the semiconductor wafer is to be divided into the device-formed part and the no-device-formed part, strong force is required to peel off the crystal structure. As a result, deformation of the device-formed part occurs, which may sometimes cause breaking and cracking.

The present invention was devised in light of the above-described circumstances and it is a main object of the invention to provide a semiconductor wafer which can be easily divided.

### SUMMARY OF THE INVENTION

A semiconductor wafer according to the present invention is a semiconductor wafer of a disk shape containing SiC as a main component, wherein the semiconductor wafer has: a first crystal layer made of a single crystal material of the SiC; and a second crystal layer made of a crystal layer of the SiC formed on the first crystal layer, wherein a diameter of the disk shape is 145 mm or more; a release-promoting layer is formed on at least one of the first crystal layer and the second crystal layer; the release-promoting layer includes voids or a release-promoting substance; and the second crystal layer has a part including nitrogen atoms at concentration of 1×10¹⁸ atoms/cm³ or more.

A semiconductor wafer manufacturing method according to the present invention is a method for manufacturing a semiconductor wafer of a disk shape containing SiC as a main component, wherein the semiconductor manufacturing method includes: a first step of forming an obstruction area which partially breaks or obstructs a SiC crystal structure on a surface of, or in vicinity of, a SiC single crystal material; and a second step of causing SiC crystals to grow with a thickness of 50 μm or more on the surface of the SiC single crystal material, on which the first step has been performed, in a mixed gas atmosphere of argon and nitrogen.

The semiconductor wafer, which is easily dividable, can be provided according to the present invention.

### BRIEF DESCRIPTION OF DRAWINGS

FIG. 1 is a diagram illustrating a configuration example of the entire system according to a first embodiment of the present invention;

FIGS. 2A, 2B and 2C are explanatory diagrams of a pretreatment for forming a layer including micro-voids;

FIGS. 3A, 3B and 3C are explanatory diagrams of a pretreatment for forming a layer including a release-promoting substance;

FIGS. 4A, 4B and 4C are explanatory diagrams of a pretreatment for forming a layer including another release-promoting substance;

FIGS. 5A, 5B and 5C are diagrams illustrating examples of the status of a cross-section obtained when cutting a SiC wafer along a plane passing through the release-promoting layer;

FIG. 6 is a diagram schematically illustrating a thermal etching process as a first example of a processing step according to a second embodiment of the present invention;

FIG. 7 is a diagram schematically illustrating a surface oxidation process as a second example of the processing step according to the second embodiment of the present invention;

FIG. 8 is a diagram schematically illustrating a plasma etching process as a third example of the processing step according to the second embodiment of the present invention; and

FIG. 9 is a table that summarizes setting conditions, impurity concentration, and a yield rate after release in respective examples.

### DESCRIPTION OF PREFERRED EMBODIMENTS

Embodiments of the present invention will be described below with reference to the drawings; however, the present invention is not limited to these embodiments. Also, in the drawings, the width, thickness, shape, etc., of each part may be sometimes expressed schematically as compared to the embodiments in order to make the descriptions clearer; however, these are just examples and do not limit the interpretation of the present invention.

Some embodiments of the present invention will be described below with reference to the drawings. Also, in the following description, a semiconductor wafer(s) is a SiC (silicon carbide) wafer(s); however, the present invention can be also applied to semiconductor wafers other than the SiC wafer(s). Possible semiconductor wafers other than the SiC wafer(s) may be GaN (gallium nitride), AlN (aluminum nitride) wafers, or diamond wafers.

### First Embodiment

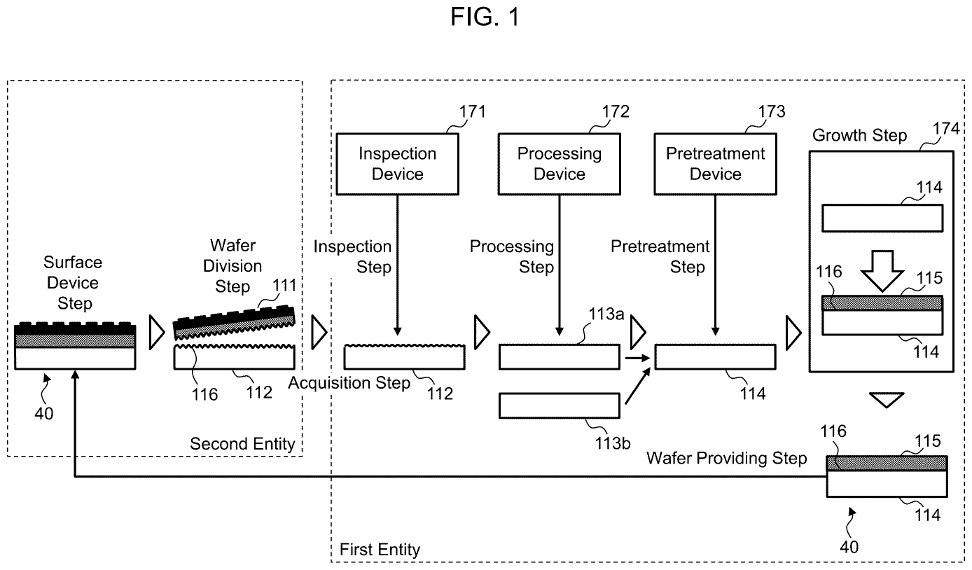

FIG. 1 illustrates a configuration example of the entire system according to a first embodiment of the present invention.

A surface device step and a wafer division step are performed at a second entity. The second entity may be a company as a device manufacturer which retrieves SiC chips from SiC wafers 40 and provides the SiC chips or devices having the SiC chips. A SiC wafer 40 is roughly divided into a base SiC crystal layer and a grown SiC crystal layer (oriented SiC crystals).

In the surface device step, a device is formed on a first main surface (surface) of the SiC wafer 40. The device may include electrodes and wiring patterns.

In the wafer division step, the SiC wafer 40 having the device is divided along a plane direction (a direction perpendicular to a thickness direction, in other words, a direction parallel with the first main surface). In this wafer division step, the SiC wafer 40 is sliced along the plane direction by, for example, a method called laser slicing using a laser device. Specifically, for example, the laser device applies a laser light (such as a pulsed laser) from a second main surface side (back side) of the SiC wafer 40 to a release-promoting layer 116 which is formed inside the SiC wafer 40 in advance. Consequently, a modified layer is formed at the release-promoting layer 116 and the SiC wafer 40 is divided, at this modified layer as a starting point, into a main wafer 111 which is a SiC wafer part having the first main surface, and a remaining wafer 112 which is a SiC wafer part having the second main surface.

The release-promoting layer 116 inside the SiC wafer 40, which is irradiated with the laser light upon the laser slicing is a layer whose SiC crystal structure is incomplete as compared to other parts or which can easily peel off due to other causes. By applying the laser light to this release-promoting layer 116 to make it a modified layer and dividing the SiC wafer 40 along the release-promoting layer 116, at the modified layer as a starting point, into the main wafer 111 and the remaining wafer 112, the SiC wafer 40 can be divided (or peeled) more easily than a case where other parts are formed as the modified layer. Its possible cause would be, for example, the release-promoting layer 116 has an incomplete crystal structure as compared to the other parts, and thereby has weak cohesive forces between atoms. Moreover, another possible reason would be that the release-promoting layer 116 easily absorbs the laser light and, therefore, it is easy to form the modified layer. There are other various possible causes; however, regardless of the cause(s), by peeling off the part including the first main surface from the SiC wafer 40 at the release-promoting layer 116 as the starting point, it is possible to divide the SiC wafer 40 into the main wafer 111 and the remaining wafer 112 by using less force. Consequently, it is possible to prevent the occurrence of deformations upon peeling-off at the device-formed part of the main wafer 111 and it is thereby possible to prevent the occurrence of breaking or cracking.

Incidentally, the release-promoting layer 116 is formed inside the SiC wafer 40 when manufacturing the SiC wafer 40 at the first entity which is different from the second entity. This method will be described later in detail.

Incidentally, in the wafer division step, the SiC wafer 40 may be divided into the main wafer 111 and the remaining wafer 112 by a method other than the above-described laser slicing. For example, the SiC wafer 40 can be also divided into the main wafer 111 and the remaining wafer 112 by removing the release-promoting layer 116 of the SiC wafer 40 by means of etching. In this case, for example, electrolytic etching, chemical etching, thermal etching, etc., can be used for the etching. By performing the wafer division step by conducing the etching as described above, the SiC wafer 40 can be divided into the main wafer 111 and the remaining wafer 112 without using the laser device. Besides the above, by using an arbitrary method to perform the processing with respect to the release-promoting layer 116 formed inside the SiC wafer 40, the SiC wafer 40 can be divided into the main wafer 111 and the remaining wafer 112.

An acquisition step, a processing step, a pretreatment step, a growth step, and a wafer providing step are performed at the first entity (moreover, in this embodiment, an inspection step is also performed between the acquisition step and the processing step as described later). The first entity is a company which provides a new service, that is, a company which conducts a service for acquiring (collecting) the remaining wafer 112 of the SiC wafer 40 from the second entity, causing the grown SiC crystals to grow on the remaining wafer 112 to reclaim the SiC wafer 40, and providing the reclaimed SiC wafer 40 to the same second entity or a different second entity. One or more second entities exist with respect to the first entity. Incidentally, the aforementioned wafer division step may be performed not at the second entity, but at the first entity.

In the acquisition step, the remaining wafer 112 is acquired from the second entity. In the processing step, the slice surface of the remaining wafer 112 is processed and a seed crystal 113a made of a SiC single crystal material is acquired.

In the pretreatment step, an obstruction area that partially breaks or obstructs the SiC crystal structure is formed on a surface of, or in the vicinity of, the seed crystal 113a obtained in the processing step or a seed crystal 113b which is newly prepared and is made of the SiC single crystal material. Consequently, a pretreatment for forming the aforementioned release-promoting layer 116 is applied to the seed crystal 113a, 113b, thereby obtaining a pretreated seed crystal 114. Incidentally, the details of the pretreatment step will be described later.

In the growth step, a new SiC wafer 40 is manufactured by causing grown SiC crystals (an example of the semiconductor crystal layer) 115 to grow on a surface of the seed crystal 114 obtained in the pretreatment step. Inside the SiC wafer 40 manufactured here, the release-promoting layer 116 is formed by the obstruction area formed in the seed crestal 114 in the pretreatment step.

In the wafer providing step, the SiC wafer 40 obtained in the growth step is provided to a second entity which is the same second entity as, or a different second entity from, the acquisition source of the remaining wafer 112.

In a conventional process to which the present invention is not applied, a part of the SiC wafer 40 corresponding to the remaining wafer 112 is ground without being separated from the main wafer 111 and ground scraps produced by the above-described grinding are discarded. On the other hand, in this embodiment, the remaining wafer 112 is separated from the main wafer 111 and is collected without being discarded as the ground scraps and the collected remaining wafer is reclaimed as a new semiconductor wafer by the first entity and is provided to the second entity. At the second entity, a device is formed on the semiconductor wafer provided by the first entity (the SiC wafer 40 reclaimed from the remaining wafer 112) and the above-obtained semiconductor wafer is then separated into the main wafer 111 and the remaining wafer 112. The remaining wafer 112 is collected by the first entity and is used as the seed crystal 114 to form the grown SiC crystals together with the release-promoting layer 116, so that it is used again as the SiC wafer 40. By repeating this, it is possible to reuse the parts of the remaining wafer 112 in the SiC wafer 40, which were conventionally ground and discarded. By doing so, the present invention makes it possible to reuse expensive SiC wafers and realize the reduction of device manufacturing costs. Furthermore, an amount of waste in the entire SiC wafer manufacturing process, including a high-temperature process, can be greatly reduced, so it is also possible to reduce the environmental load.

The processing step may be performed by a processing device 172, the pretreatment step may be performed by a pretreatment device 173, and the growth step may be performed by a growth device 174 (the inspection step described later may be performed by an inspection device 171).

Of the steps at the first entity, the acquisition step, the processing step, the pretreatment step, the growth step, and the wafer providing step will be firstly explained below and then the inspection step will be explained later.

### Acquisition Step

In the acquisition step, the remaining wafer(s) 112 is acquired from one or more second entities. An arbitrary number of remaining wafers 112 may be sent to the first entity at any timing of the second entity; or regarding each of one or more second entities, an acquisition schedule including the number of the remaining wafer(s) to be acquired from the relevant second entity and acquisition time may be shared between that second entity and the first entity and the remaining wafer(s) 112 may be acquired from that second entity according to the acquisition schedule. Incidentally, when the wafer division step is performed at the first entity, the acquisition step is not required.

### Processing Step

The processing in the processing step includes grinding a slice surface (typically, grinding and/or polishing) and removing a work-affected layer including the ground slice surface. The processing device 172 may include, for example, a device which grinds and/or polishes the slice surface (for example, a grinder), and a device which removes the work-affected layer, and these devices may be an integrated device (specifically speaking, one device may be used to perform grinding and removal). For example, the processing device 172 may be a device which performs grinding and polishing by, for example, a CMP (Chemical Mechanical Polishing) method.

In the processing step, a seed crystal 113a is obtained as a result of the processing of the remaining wafer 112. The seed crystal 113a may be composed of base SiC crystals as a main component or may be composed of the base SiC crystals and some of oriented SiC crystals. Alternatively, instead of the seed crystal 113a, a new SiC single crystal material may be prepared and this may be used as a seed crystal 113b.

### Pretreatment Step

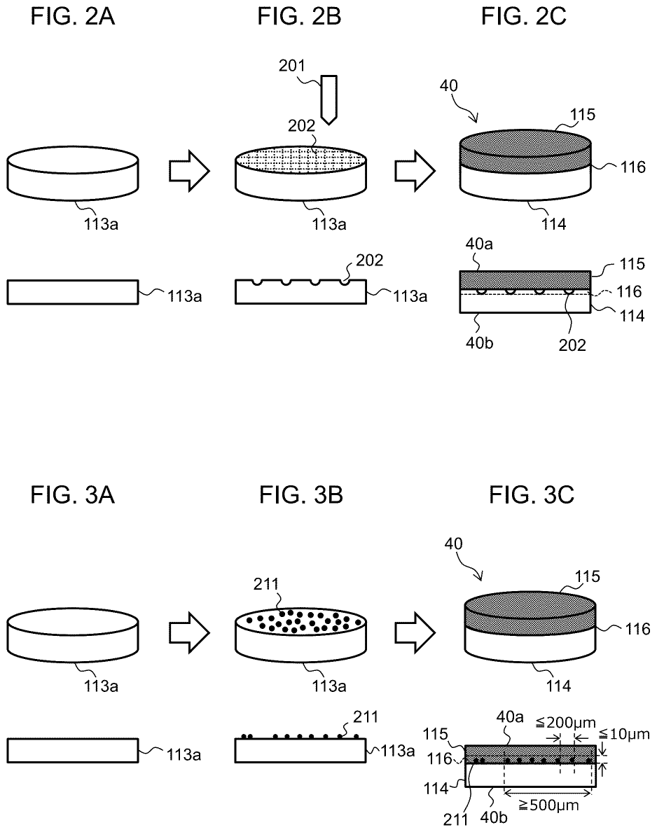

The pretreatment device 173 forms the obstruction area which partially breaks or obstructs the formation of the crystal structure when causing the grown SiC crystals to grow on a surface of, or in the vicinity of, the seed crystal 113a, 113b in the next growth step. Because of the existence of this obstruction area, the release-promoting layer 116 which can be more easily peeled off than other parts is formed inside the SiC wafer 40 manufactured from the seed crystal 113a, 113b in the growth step. Specifically, for example, the obstruction area is formed on the seed crystal 113a, 113b by the pretreatment device 173 executing any one of processing treatments respectively explained below with reference to FIGS. 2A, 2B and 2C to FIGS. 4A, 4B and 4C as the pretreatment.

FIGS. 2A, 2B and 2C are explanatory diagrams of the pretreatment for forming a layer including micro-voids as the release-promoting layer 116. FIG. 2A illustrates a schematic diagram of the seed crystal 113a before the processing; FIG. 2B illustrates how the processing is performed in the pretreatment on the seed crystal 113a; and FIG. 2C illustrates a schematic diagram of the SiC wafer 40 manufactured by using the pretreated seed crystal 114. In these diagrams, an upper part shows a perspective view and a lower part shows an enlarged sectional view, respectively.

In the pretreatment step, for example, as illustrated in FIG. 2B, grooves 202 by laser processing are formed in the surface of the seed crystal 113a by applying pulsed laser light in a lattice-like pattern at a certain interval from a laser 201, which is the pretreatment device 173, to the surface of the seed crystal 113a. In the subsequent growth step, the seed crystal 113a in which these grooves 202 are formed is used as the pretreated seed crystal 114 and the SiC crystals are caused to grow with the thickness of 50 μm or more on its surface, thereby forming the grown SiC crystals 115. Accordingly, for example, as illustrated in FIG. 2C, voids formed by the grooves 202 occur at a certain interval between the seed crystal 114 and the grown SiC crystals 115 and the crystal structure is partially broken by these voids, so that a layer 116 which can be easily peeled off along the voids is formed. Consequently, the SiC wafer 40 having the release-promoting layer 116 between the first main surface 40a on the front side (the grown SiC crystals 115 side) and the second main surface 40b on the back side (the seed crystal 114 side).

Incidentally, regarding the grooves 202 formed in the surface of the seed crystal 113a in the pretreatment step, the maximum depth of the grooves 202 should preferably be 1 μm or more. Consequently, it becomes possible to form the release-promoting layer 116 in the area including the grooves 202 while causing the SiC crystals to grow sufficiently in the growth step.

FIGS. 3A, 3B and 3C are explanatory diagrams of the pretreatment for forming a layer including a substance to promote the release as the release-promoting layer 116 (hereinafter referred to as a “release-promoting substance”). FIG. 3A illustrates a schematic diagram of the seed crystal 113a before the processing; FIG. 3B illustrates how the processing is performed in the pretreatment on the seed crystal 113a; and FIG. 3C illustrates a schematic diagram of the SiC wafer 40 manufactured by using the pretreated seed crystal 114. In these diagrams, an upper part shows a perspective view and a lower part shows an enlarged sectional view, respectively.

In the pretreatment step, for example, as illustrated in FIG. 3B, fine particles 211 containing carbon as its main component are distributed and placed on the surface of the seed crystal 113a. In the subsequent growth step, the seed crystal 113a on the surface of which these fine particles 211 are distributed and placed is used as the pretreated seed crystal 114 and the SiC crystals are caused to grow on its surface with the thickness of 50 μm or more, thereby forming the grown SiC crystals 115. Accordingly, for example, as illustrated in FIG. 3C, the fine particles 211 are placed dispersedly and sandwiched between the seed crystal 114 and the grown SiC crystals 115 and the formation of the crystal structure is obstructed by these fine particles 211, thereby forming the layer 116 having an incomplete crystal structure. Consequently, the SiC wafer 40 having the release-promoting layer 116 is manufactured between the first main surface 40a on the front side (the grown SiC crystals 115 side) and the second main surface 40b on the back side (the seed crystal 114 side).

Incidentally, regarding the fine particles 211 which contain carbon as the main component and which are distributed and placed on the surface of the seed crystal 113a in the pretreatment step, it is preferable that the fine particles 211 should be fine particles of graphite or diamond and their particle size should be 10 μm or less. Consequently, it becomes possible to form the release-promoting layer 116 in the area including the fine particles 211 while causing the SiC crystals to grow sufficiently in the growth step.

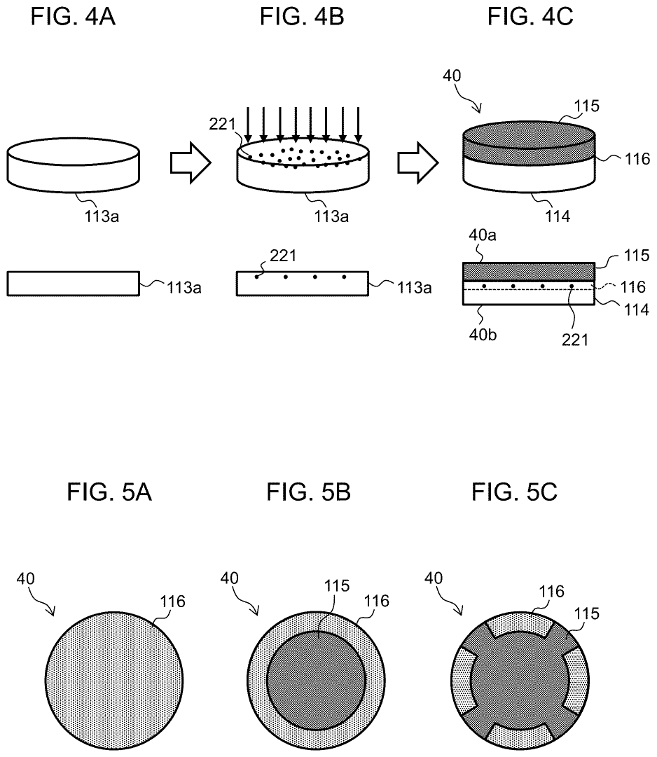

FIGS. 4A, 4B and 4C are explanatory diagrams of the pretreatment for forming a layer including another release-promoting substance, which is different from the one used in FIGS. 3A, 3B and 3C, as the release-promoting layer 116. FIG. 4A illustrates a schematic diagram of the seed crystal 113a before the processing; FIG. 4B illustrates how the processing is performed in the pretreatment on the seed crystal 113a; and FIG. 4C illustrates a schematic diagram of the SiC wafer 40 manufactured by using the pretreated seed crystal 114. In these diagrams, an upper part shows a perspective view and a lower part shows an enlarged sectional view, respectively.

In the pretreatment step, for example, as illustrated in FIG. 4B, ions 221 are injected into the seed crystal 113a through its surface. Specifically, for example, the ions 221 are injected, dispersed, and placed near the surface of the seed crystal 113a by accelerating the ions 221 generated at an ion source and shooting the ions 221 from outside towards the surface of the seed crystal 113a. In the subsequent growth step, the seed crystal 113a inside which the ions 221 are dispersed and placed is used as the pretreated seed crystal 114 and the SiC crystals are caused to grow on its surface with the thickness of 50 μm or more, thereby forming the grown SiC crystals 115. Accordingly, for example, as illustrated in FIG. 4C, the ions 221 are placed dispersedly near the boundary between the seed crystal 114 and the grown SiC crystals 115 and the formation of the crystal structure is obstructed by these ions 221, thereby forming the layer 116 having the incomplete crystal structure. Consequently, the SiC wafer 40 having the release-promoting layer 116 is manufactured between the first main surface 40a on the front side (the grown SiC crystals 115 side) and the second main surface 40b on the back side (the seed crystal 114 side). In the subsequent wafer division step, when the release-promoting layer 116 inside the SiC wafer 40 is removed by etching as described above, the release-promoting layer 116 should preferably be formed by the method explained with reference to FIGS. 4A, 4B and 4C.

Incidentally, it is preferable that ions of any one or more types of Si, C, Al, B, P, N, O, H, noble gas elements, and rare earth elements should be used as the ions 221 injected into the seed crystal 113a in the pretreatment step. Consequently, it becomes possible to form the release-promoting layer 116 in the area including the ions 221 while causing the SiC crystals to grow sufficiently in the growth step.

In the pretreatment step, the seed crystal 114 is obtained by the pretreatment device 173 by performing any one of the above-described pretreatments on the seed crystal 113a, 113b. Incidentally, regarding FIGS. 2A, 2B and 2C to FIGS. 4A, 4B and 4C, the examples of performing the pretreatment on the seed crystal 113a obtained in the processing step have been explained; however, it is also possible to obtain the seed crystal 114 by performing similar pretreatment on the newly prepared seed crystal 113b.

### Growth Step

At the growth device 174, the grown SiC crystals (oriented SiC crystals) 115 are caused to grow with the thickness of 50 μm or more on the seed crystal 114. Such crystal growth may be performed by a sublimation method or a CVD (Chemical Vapor Deposition) method or by other methods. As a result, as explained with reference to FIGS. 2A, 2B and 2C to FIGS. 4A, 4B and 4C, a new SiC wafer 40 is obtained, which is composed of the seed crystal 114 that is a crystal layer of the single crystal material of SiC, and the grown SiC crystals 115 made of a crystal layer of SiC formed on the seed crystal 114, and which has the release-promoting layer 116 between the first main surface 40a on the grown SiC crystals 115 side and the second main surface 40b on the seed crystal 114 side. In this SiC wafer 40, the incomplete crystal structure by the voids formed by the grooves 202, the fine particles 211, or the ions 221 is formed as the release-promoting layer 116 in at least one of the seed crystal 114 and the grown SiC crystals 115.

Incidentally, the release-promoting layer 116 should preferably be formed, as the example illustrated in FIG. 3C, within the range of 10 μm or less in the thickness direction (in the vertical direction in the drawing) perpendicular to the first main surface 40a and the second main surface 40b. Specifically, it is preferable that when observing the cross-section of the SiC wafer 40 in the thickness direction at an arbitrary position including the release-promoting layer 116, the thickness of the release-promoting layer 116 in that cross-section should be 10 μm or less. Consequently, the thickness of the release-promoting layer 116 can be made thinner than a height difference of a slice surface (generally about 20 to 50 μm) generated when dividing a conventional SiC wafer, which does not have the release-promoting layer 116, by laser slicing, so that the amount of ground scraps produced in the processing step can be reduced and the amount of SiC waste can thereby be reduced. Incidentally, the release-promoting layer 116 is part of the seed crystal 114 or the grown SiC crystals 115 as illustrated in FIGS. 2A, 2B and 2C to FIGS. 4A, 4B and 4C.

Moreover, in the release-promoting layer 116, as illustrated in FIG. 3C, the voids formed by the grooves 202 or the release-promoting substance composed of the fine particles 211 or the ions 221 should preferably be distributed at the interval of 200 μm or less throughout the range of at least 500 μm or more in the plane direction (the horizontal direction in the diagram) in parallel with the first main surface 40a and the second main surface 40b. Consequently, when the first entity divides the SiC wafer 40 into the main wafer 111 and the remaining wafer 112 in the wafer division step, it is possible to form the release-promoting layer 116 which can be easily peeled off with little force.

FIGS. 5A, 5B and 5C are diagrams illustrating examples of the status of a cross-section of the SiC wafer 40 illustrated in FIG. 2C as taken along a plane in parallel with the first main surface 40a and passing through at least part of the release-promoting layer 116 FIG. 2C. FIG. 5A shows an example of the cross-section when the release-promoting layer 116 is formed across the entire face in the plane direction at a position of a specified depth inside the SiC wafer 40. FIG. 5B shows an example of the cross-section when the release-promoting layer 116 is formed around the entire circumference of an area within the SiC wafer 40 in the vicinity of its outer circumference. FIG. 5C shows an example of the cross-section when the release-promoting layer 116 is formed in some areas within the SiC wafer 40 in the vicinity of its outer circumference. Incidentally, the release-promoting layer 116 may be formed in other arrangements besides these.

As indicated in the above-described respective examples, the release-promoting layer 116 may be formed across the entire face in the plane direction or may be formed only in some area(s) when the SiC wafer 40 is viewed from the direction of the first main surface 40a. If the release-promoting layer 116 is distributed throughout a certain range, for example, throughout the range of 500 μm or more in the plane direction, the release-promoting layer 116 can be formed in an arbitrary area(s) inside the SiC wafer 40.

### Wafer Providing Step

A new SiC wafer 40 that is composed of the seed crystal 114 and the grown SiC crystals 115 which have grown is provided to the same second entity as, or a different second entity from, the acquisition source of the remaining wafer which is the base of the relevant SiC wafer. Accordingly, the acquired remaining wafer 112 is reclaimed as the above-described new SiC wafer 40 and provided to the second entity, so that the main wafer can be obtained from that SiC wafer 40 at the second entity.

The acquisition step, the processing step, the pretreatment step, the growth step, and the wafer providing step have been explained above.

This embodiment has the inspection step of inspecting the slice surface of the acquired remaining wafer 112 between the acquisition step and the processing step. The inspection step is, for example, as described below.

### Inspection Step

The inspection in the inspection step includes measuring at least one of a height difference of the slice surface and the thickness of the work-affected layer having the slice surface. In this embodiment, both of the above are measured. The height difference of the slice surface is the height difference of an uneven shape of the surface caused by the laser irradiation or the division into the main wafer 111 and the remaining wafer 112 in the aforementioned wafer division step.

The inspection step is performed by the inspection device 171. The inspection device 171 may include a laser microscope and a Raman spectrometer. The height difference of the slice surface may be measured by the laser microscope. The thickness of the work-affected layer may be measured by using the Raman spectrometer. Regarding either the height difference of the slice surface or the thickness of the work-affected layer, the measurement methods do not have to be limited to the above-mentioned examples. For example, the height difference of the slice surface may be measured by a white-light interferometer or a contact-type shape measuring machine.

At least one of the following (x) and (y) may be performed.
(x) The processing in the processing step includes deciding a grinding amount of the slice surface based on at least one of the measured height difference of the slice surface and the measured thickness of the work-affected layer of the acquired remaining wafer 112 and grinding the slice surface according to the decided grinding amount. Consequently, the slice surface processing can be performed appropriately (with little excess or deficiency) according to the quality (status) of the acquired remaining wafer 112. For example, if a PV value (maximum valley depth) is measured as an example of the height difference of the slice surface and the work-affected layer depth is measured as an example of the thickness of the work-affected layer, the grinding amount may be as follows: the grinding amount=the PV value+(the work-affected layer depth×N). N may be an arbitrary value larger than 0 (for example, an arbitrary natural number). A processing command associated with the information indicating the grinding amount may be input to the processing device 172 (or a control device for the processing device 172) and the processing device 172 may thereby perform the slice surface processing according to the grinding amount. The “grinding amount” may be defined by a parameter value regarding each of one or more parameter items. For example, duration of the processing by the processing device 172, power of the processing (such as a temperature and pressure), etc., may be adopted as examples of the parameter items.
(y) In the growth step, the thickness of the grown SiC crystals to be caused to grow is decided based on at least one of the measured height difference of the slice surface and the measured thickness of the work-affected layer of the remaining wafer 112 and the grown SiC crystals are caused to grow as much as the decided thickness. Consequently, the crystal growth can be performed appropriately (with little excess or deficiency) according to the quality (status) of the acquired remaining wafer 112. For example, the thickness to be caused to grow may be decided based on at least one of X, Y, Z, and α. Specifically, for example, the thickness to be caused to grow may be X−Y+Z+α. X may be a required thickness when starting the surface device step or the wafer division step at the second entity (the thickness required by the second entity). Y may be the thickness of the grown SiC crystals when received at the first entity. Z may be the grinding amount decided in the above-mentioned (x). The value of α may be an arbitrary value (for example, approximately 50 μm) decided as a processing allowance (processing margin) for removing the unevenness after the growth for the purpose of planarization. A crystal growth command associated with the information indicating the thickness to be caused to grow may be input to the growth device 174 (or a control device for the growth device 174) and the growth device 174 may thereby cause the grown SiC crystals to grow as much as that thickness on the seed crystal.

### EXAMPLES

Next, a specific explanation will be provided about examples for verifying the advantageous effect of the release-promoting layer 116 regarding the above-described SiC wafer 40 formed by causing the grown SiC crystals 115 to grow on the seed crystal 114.

### Example 1

In the pretreatment step, a disk-shaped SiC substrate (diameter: 150 mm) was obtained, this substrate was used as the seed crystal 113a, and hydrogen ions were injected as the ions 221 for forming the release-promoting layer 116 as explained with reference to FIG. 4B. Under this circumstance, conditions for injecting the hydrogen ions were set as an accelerating voltage of 170 kev, a dose of 8×10¹⁵ ions/cm², and a temperature of 500° C.

In the subsequent growth step, the SiC substrate into which the hydrogen ions were injected in the pretreatment step was set in a container filled with base powder. In Example 1, a mixture of a first raw material consisting of SiC and a second raw material containing yttrium (Y) which is a rare earth element was used as the base powder. Also, in Example 1, a mixing ratio of the first raw material and the second raw material in the base powder was adjusted so that a weight ratio of yttrium to the weight of SiC which is the first raw material would become 6.4%. Then, this container was placed at a position that would make the temperature range within a resistance heating furnace (firing furnace) become within a set temperature ±50° C.; and the set temperature in a mixed gas atmosphere of argon and nitrogen was set as 2450° C. and a heat treatment was performed for 20 hours, thereby causing the SiC single crystals to grow for about 200 μm on the SiC substrate as the seed crystal 114 and then forming the grown SiC crystals 115. When doing so, a nitrogen gas flow rate was adjusted so that a calculated nitrogen gas partial pressure within the furnace would become 0.0025 atm. Consequently, as explained with reference to FIGS. 4A, 4B and 4C, the SiC wafer 40 was obtained, which had the seed crystal 114 and the grown SiC crystals 115 and in which the incomplete crystal structure formed by the hydrogen ions injected into the seed crystal 114 was formed as the release-promoting layer 116 between the first main surface 40a and the second main surface 40b.

Furthermore, mechanical polishing was performed on the above-obtained SiC wafer 40 so that both sides of the SiC wafer 40 would become respectively flat. When doing so, the amount of polishing on the surface on the grown SiC crystals 115 side (the first main surface 40a) and the opposite-side surface (the second main surface 40b) was adjusted, respectively, so that stock removal on the grown SiC crystals 115 side would become 50 μm and the thickness of the SiC wafer 40 after polishing would become 350 μm.

A SiC-MOSFET device was formed by performing the surface device step on the thus-obtained polished SiC wafer 40. Then, the wafer division step was performed by applying a pulsed laser with a wavelength 1064 nm through the back side (the second main surface 40b side) of the SiC wafer 40 to the release-promoting layer 116 and scanning this laser light in the plane direction, and the SiC wafer 40 was peeled off at the release-promoting layer 116. The laser light irradiation conditions then used were irradiation fluence of 100 J/cm² and a pulse width of 10 ns, and a position located 200 μm from the back side (the second main surface 40b) of the SiC wafer 40 was set as a laser focal position. Consequently, the SiC wafer 40 with the SiC-MOSFET device formed thereon was divided into the main wafer 111 and the remaining wafer 112.

### Example 2

In Example 2, a disk-shaped SiC substrate with a larger diameter than that of Example 1 (diameter: 200 mm) was used as the seed crystal 113a. Then, the respective steps were performed with conditions similar to those of Example 1 and the SiC wafer 40 with the SiC-MOSFET device formed thereon was divided into the main wafer 111 and the remaining wafer 112.

### Example 3

In Example 3, the pretreatment step was performed with the same conditions as those for Examples 1 and 2 by using a SiC substrate (diameter: 150 mm) of the same shape as that in Example 1 as the seed crystal 113a. Then, by performing the growth step by adjusting the mixing ratio of the first raw material and the second raw material in the base powder so as to make the weight ratio of yttrium to the weight of SiC become 0.3%, and setting other conditions as the same as those for Examples 1 and 2, the SiC wafer 40 was thereby obtained, which had the seed crystal 114 and the grown SiC crystals 115 and in which the incomplete crystal structure formed by the hydrogen ions injected into the seed crystal 114 was formed as the release-promoting layer 116 between the first main surface 40a and the second main surface 40b. The surface device step and the wafer division step were performed with respect to this SiC wafer 40 with conditions similar to those for Example 1 and then the SiC wafer 40 with the SiC-MOSFET device formed thereon was divided into the main wafer 111 and the remaining wafer 112.

### Example 4

In Example 4, the pretreatment step was performed with the same conditions as those for Examples 1 to 3 by using a SiC substrate (diameter: 150 mm) of the same shape as that in Examples 1 and 3 as the seed crystal 113a. Then, by performing the growth step by using only the first raw material consisting of SiC as the base powder and setting other conditions as the same as those for Example 1 to 3, the SiC wafer 40 was thereby obtained, which had the seed crystal 114 and the grown SiC crystals 115 and in which the incomplete crystal structure formed by the hydrogen ions injected into the seed crystal 114 was formed as the release-promoting layer 116 between the first main surface 40a and the second main surface 40b. The surface device step and the wafer division step were performed with respect to this SiC wafer 40 with conditions similar to those for Examples 1 to 3 and then the SiC wafer 40 with the SiC-MOSFET device formed thereon was divided into the main wafer 111 and the remaining wafer 112.

### Example 5

In Example 5, the pretreatment step was performed with the same conditions as those for Examples 1 to 4 by using a SiC substrate (diameter: 150 mm) of the same shape as that in Examples 1, 3, and 4 as the seed crystal 113a. Then, by performing the growth step by using only the first raw material consisting of SiC as the base powder in a manner similar to Example 4, adjusting a nitrogen gas flow rate so as to make a calculated nitrogen gas partial pressure within the furnace become 0.0000003 atm, and setting other conditions as the same as those for Example 1 to 4, the SiC wafer 40 was thereby obtained, which had the seed crystal 114 and the grown SiC crystals 115 and in which the incomplete crystal structure formed by the hydrogen ions injected into the seed crystal 114 was formed as the release-promoting layer 116 between the first main surface 40a and the second main surface 40b. The surface device step and the wafer division step were performed with respect to this SiC wafer 40 with conditions similar to those for Examples 1 to 4 and then the SiC wafer 40 with the SiC-MOSFET device formed thereon was divided into the main wafer 111 and the remaining wafer 112.

### Example 6

In Example 6, the pretreatment step was performed with the same conditions as those for Examples 1 to 5 by using a SiC substrate (diameter: 150 mm) of the same shape as that in Examples 1 and 3 to 5 as the seed crystal 113a. Then, by performing the growth step by using only the first raw material consisting of SiC as the base powder in a manner similar to Examples 4 and 5 without introducing the nitrogen gas, but in an argon gas atmosphere, and setting other conditions as the same as those for Example 1 to 5, the SiC wafer 40 was thereby obtained, which had the seed crystal 114 and the grown SiC crystals 115 and in which the incomplete crystal structure formed by the hydrogen ions injected into the seed crystal 114 was formed as the release-promoting layer 116 between the first main surface 40a and the second main surface 40b. The surface device step and the wafer division step were performed with respect to this SiC wafer 40 with conditions similar to those for Examples 1 to 5 and then the SiC wafer 40 with the SiC-MOSFET device formed thereon was divided into the main wafer 111 and the remaining wafer 112.

### Example 7

In Example 7, the pretreatment step was performed with the same conditions as those for Examples 1 to 6 by using a SiC substrate (diameter: 100 mm) whose diameter was smaller than that in other examples as the seed crystal 113a. Then, by performing the growth step by using only the first raw material consisting of SiC as the base powder in a manner similar to Examples 4 to 6 without introducing the nitrogen gas, but in the argon gas atmosphere in a manner similar to Example 6, and setting other conditions as the same as those for Example 1 to 6, the SiC wafer 40 was thereby obtained, which had the seed crystal 114 and the grown SiC crystals 115 and in which the incomplete crystal structure formed by the hydrogen ions injected into the seed crystal 114 was formed as the release-promoting layer 116 between the first main surface 40a and the second main surface 40b. The surface device step and the wafer division step were performed with respect to this SiC wafer 40 with conditions similar to those for Examples 1 to 6 and then the SiC wafer 40 with the SiC-MOSFET device formed thereon was divided into the main wafer 111 and the remaining wafer 112.

### Example 8

In Example 8, the pretreatment step was performed with the same conditions as those for Examples 1 to 7 by using a SiC substrate (diameter: 150 mm) of the same shape as that in Examples 1 and 3 to 6 as the seed crystal 113a. In the subsequent growth step, a mixture of the first raw material consisting of SiC and the second raw material containing cerium (Ce) which is another rare earth element different from that used in Examples 1 to 3 was used as the base powder. Under this circumstance, the mixing ratio of the first raw material and the second raw material in the base powder was adjusted so that the weight ratio of cerium to the weight of SiC which is the first raw material would become 10.2%. Then, by performing the growth step by setting other conditions as the same as those for Examples 1 to 7, the SiC wafer 40 was thereby obtained, which has the seed crystal 114 and the grown SiC crystals 115 and in which the incomplete crystal structure formed by the hydrogen ions injected into the seed crystal 114 was formed as the release-promoting layer 116 between the first main surface 40a and the second main surface 40b. The surface device step and the wafer division step were performed with respect to this SiC wafer 40 with conditions similar to those for Examples 1 to 7 and then the SiC wafer 40 with the SiC-MOSFET device formed thereon was divided into the main wafer 111 and the remaining wafer 112.

### Example 9

In Example 9, the pretreatment step was performed with the same conditions as those for Examples 1 to 8 by using a SiC substrate (diameter: 150 mm) of the same shape as that in Examples 1, 3 to 6, and 8 as the seed crystal 113a. In the subsequent growth step, similarly to Examples 1 and 2, a mixture of the first raw material consisting of SiC and the second raw material containing yttrium which were combined so that the weight ratio of yttrium to the weight of SiC would become 6.4% was used as the base powder. Then, by performing the growth step in the argon gas atmosphere without introducing the nitrogen gas after retaining the set temperature within the furnace at 2450° C. until the elapse of 12 hours and then, after the elapse of 12 hours, in the mixed gas atmosphere of argon and nitrogen at the nitrogen gas flow rate adjusted so as to make the calculated nitrogen gas partial pressure within the furnace become 0.0025 atm, and by setting other conditions as the same as those for Example 1 to 8, the SiC wafer 40 was thereby obtained, which has the seed crystal 114 and the grown SiC crystals 115 and in which the incomplete crystal structure formed by the hydrogen ions injected into the seed crystal 114 was formed as the release-promoting layer 116 between the first main surface 40a and the second main surface 40b. The surface device step and the wafer division step were performed with respect to this SiC wafer 40 with conditions similar to those for Examples 1 to 8 and then the SiC wafer 40 with the SiC-MOSFET device formed thereon was divided into the main wafer 111 and the remaining wafer 112.

### Example 10

In Example 10, the pretreatment step was performed with the same conditions as those for Examples 1 to 9 by using a SiC substrate (diameter: 150 mm) of the same shape as that in Examples 1, 3 to 6, 8, and 9 as the seed crystal 113a. In the subsequent growth step, similarly to Examples 1, 2, and 9, the mixture of the first raw material consisting of SiC and the second raw material containing yttrium which were combined so that the weight ratio of yttrium to the weight of SiC would become 6.4% was used as the base powder. Then, by performing the growth step in the argon gas atmosphere without introducing the nitrogen gas after retaining the set temperature within the furnace at 2450° C. until the elapse of 9 hours and then, after the elapse of 9 hours, in the mixed gas atmosphere of argon and nitrogen at the nitrogen gas flow rate adjusted so as to make the calculated nitrogen gas partial pressure within the furnace become 0.0025 atm, and by setting other conditions as the same as those for Example 1 to 9, the SiC wafer 40 was thereby obtained, which has the seed crystal 114 and the grown SiC crystals 115 and in which the incomplete crystal structure formed by the hydrogen ions injected into the seed crystal 114 was formed as the release-promoting layer 116 between the first main surface 40a and the second main surface 40b. The surface device step and the wafer division step were performed with respect to this SiC wafer 40 with conditions similar to those for Examples 1 to 9 and then the SiC wafer 40 with the SiC-MOSFET device formed thereon was divided into the main wafer 111 and the remaining wafer 112.

### Release Performance Check

Regarding each of the above-described Examples 1 to 10, 100 samples of the SiC wafers 40 were prepared for each Example, respective release surfaces of the main wafer 111 and the remaining wafer 112 which were obtained after the wafer division step were irradiated with a halogen lamp and the status of these release surfaces were inspected by visual inspection. As a result, the release performance in each Example was checked by evaluating a yield rate after release by determining it is defective when there are breaks or cracks of 1 mm or more in either one of the release surfaces.

### Impurity Concentration Check

Regarding each of the above-described Examples 1 to 10, the layer of the SiC-MOSFET device formed in the surface device step was removed from the surface of the SiC wafer 40 on the grown SiC crystals 115 side (the first main surface 40a) before the wafer division step and further polishing the SiC wafer 40 as much as a specified thickness to expose the grown SiC crystals 115 at the depth corresponding to that thickness, so the concentration of impurities (nitrogen and rare earth elements) in this exposed surface was thereby measured. By performing such measurement regarding each depth (thickness) of 5 μm, 10 μm, 25 μm, and 55 μm from the first main surface 40a after removing the device layer, the concentration of nitrogen and rare earth elements in the grown SiC crystals 115 at these depths from the first main surface 40a in the thickness direction perpendicular to the first main surface 40a was checked. Incidentally, Dynamic Secondary Ion Mass Spectrometry (D-SIMS) was then used for the measurement of the impurity concentration.

### Analysis of Each Example

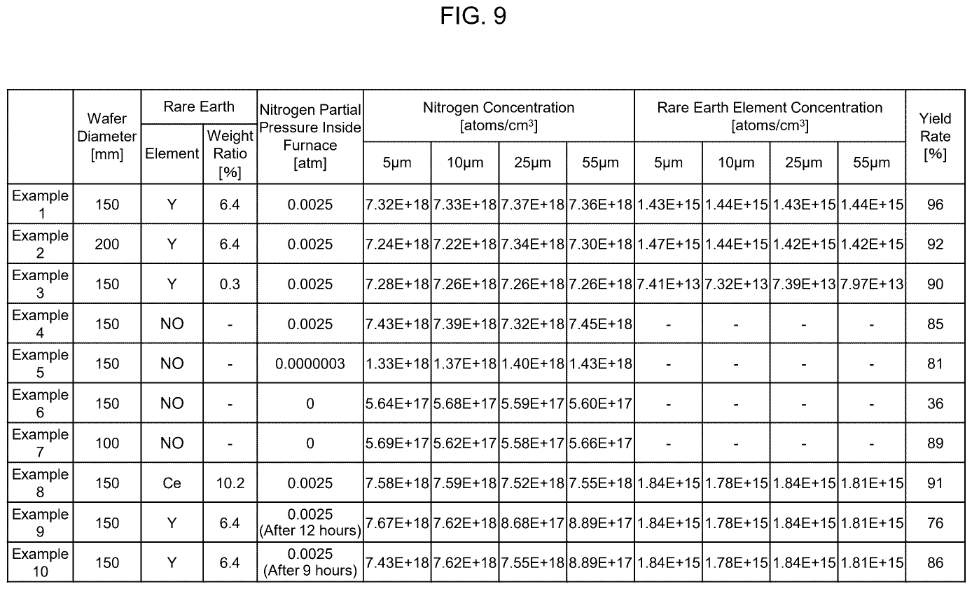

FIG. 9 is a table that summarizes setting conditions for each of Examples 1 to 10 (the wafer diameter, the rare earth element type and the weight ratio to SiC in the growth step, and the nitrogen gas partial pressure within the furnace), the concentration of impurities (nitrogen and the rare earth elements) in the grown SiC crystals 115 at the respective depths (5 μm, 10 μm, 25 μm, and 55 μm) from the first main surface 40a, and the yield rate after the release.

It can be seen based on the relationship between the setting conditions and the yield rate for each Example as indicated in the table in FIG. 9 that the release performance at the release-promoting layer 116 can be enhanced and the occurrence of breaks or cracks while performing the wafer division step can be prevented by conducting a treatment to control a ratio of nitrogen contained in the mixed gas to achieve a specified nitrogen concentration and a treatment to cause a trace amount of the rare earth element(s) to be contained in the grown SiC crystals 115 in the growth step for causing the grown SiC crystals 115 to grow on the seed crystal 114 and recover the thickness of the SiC wafer 40. Moreover, it can be seen that the advantageous effects obtained by these treatments increase more when the size of the SiC wafer 40 (the disk shape diameter) becomes larger. Specifically, when the disk shape diameter of the SiC wafer 40 is 145 mm or more, if the concentration of the nitrogen atoms in the grown SiC crystals 115 at the depth of 25 to 55 μm from the first main surface 40a in the thickness direction perpendicular to the first main surface 40a is 1×10¹⁸ atoms/cm³ or more (Examples 1 to 5 and 8), and/or if the grown SiC crystals 115 contain the rare earth element(s) at the concentration of 5×10¹³ atoms/cm³ or more (Examples 1 to 4 and 8 to 10), it becomes possible to enhance the release performance at the release-promoting layer 116 sufficiently and make the yield rate after release become a high value. More specifically, in Examples 1 to 5 and 8, when the grown SiC crystals 115 have the thickness of 55 μm or more, the concentration of the nitrogen atoms in the grown SiC crystals 115 at the depth of 55 μm from the first main surface 40a in the thickness direction perpendicular to the first main surface 40a is 1×10¹⁸ atoms/cm³ or more. Specifically speaking, regarding the reclaim of the SiC wafer to which the present invention is applied, it becomes possible to enhance the yield when reclaiming the wafer by performing the above-described treatments in the growth step.

Incidentally, a possible reason for the successful enhancement of the release performance at the release-promoting layer 116 by the above-described treatments would be, for example, that stress and warpage which may occur when applying the laser light in the wafer division step could be reduced by setting the concentration of the impurities (nitrogen and rare earth elements) in the grown SiC crystals 115 within an appropriate range. Moreover, it can be presumed that as the rare earth element(s) exists as the impurities in the grown SiC crystals 115, an atomic vacancy concentration in SiC lattices in the area where the laser light is focused within the release-promoting layer 116 increases and, as a result, it would become possible to easily break Si—C bonds in that area. In any case, it can be seen based on the relationship between the setting conditions for each of Examples 1 to 10 and the impurity concentration in the grown SiC crystals 115 at the respective depths from the first main surface 40a and the yield rate after release that the release performance of the release-promoting layer 116 can be enhanced by the aforementioned treatments.

Incidentally, Examples 1 to 10 have described the examples where the wafer division step was performed by laser slicing using the pulsed laser; however, even when the wafer division step is performed by other methods, it is assumed that the release performance of the release-promoting layer 116 can be enhanced by similar treatments. Moreover, Examples 1 to 10 have described the examples where the release-promoting layer 116 was formed inside the SiC wafer 40 by injecting the hydrogen ions into the seed crystal 114; however, even when the release-promoting layer 116 is formed by injecting other ions or when the release-promoting layer 116 is formed by other methods (such as the incomplete crystal structure caused by the voids formed by the grooves 202 as explained with reference to FIGS. 2A, 2B and 2C and the fine particles 211 as explained with reference to FIGS. 3A, 3B and 3C), it is assumed that the release performance of the release-promoting layer 116 can be enhanced by similar treatments. Besides this, as long as the semiconductor wafer of the disk shape which contains SiC as the main component and inside which the release-promoting layer 116 is formed is used, the release performance of the release-promoting layer 116 can be enhanced by conducting the aforementioned treatments in the growth step.

### Second Embodiment

A second embodiment will be explained. When doing so, the difference(s) between the second embodiment and the first embodiment will be mainly explained and an explanation about what the second embodiment and the first embodiment have in common will be omitted or simplified.

In the second embodiment, the crystal growth in the growth step is performed by using a method disclosed in a prior application WO2023/067736 by the same applicant as that of the present application (the above-described method will be hereinafter referred to as an “NGK method” for convenience based on the notation of the applicant). Specifically speaking, in the growth step, SiC single crystals as a seed crystal and a SiC powder layer in a state of being in contact with each other are placed within a container and a heat treatment is performed by placing the container in a firing furnace, thereby causing the SiC single crystals to grow on the seed crystal. If the NGK method is employed, it is possible to obtain the SiC single crystals (grown SiC crystals) which have a smaller BPD density than that obtained by the sublimation method and which has the BPD density of the same degree as that obtained by the CVD method. The second embodiment can incorporate by reference the entire or part of the technology disclosed in WO2023/067736.

Incidentally, when the crystal growth is performed by the NGK method, the processed surface may have lower flatness as compared to the case when the crystal growth is performed by the sublimation method or the CVD method; and the processed flat surface does not have to be completely flat. Specifically, for example, this will be explained below.

When homoepitaxial growth is caused on the seed crystal by the sublimation method or the CVD method, essential conditions are normally that the surface to grow should be flat at the atomic level and no work-affected layer should exist. Otherwise, the epitaxially grown surface may become uneven and defects such as dislocations may be generated in the crystals.

Meanwhile, the SiC wafer is rigid and is stable against heat and chemicals. So, when the surface planarization and the processing damage removal are performed by the CMP method after slicing and grinding, it is extremely time-consuming and a consumption amount of polishing slurry, polishing pads, etc., is large.

Therefore, in the processing step in this embodiment, the work-affected layer is removed by a thermal etching process, a surface oxidation process, or a plasma etching process (that is, any arbitrary process which results in lower flatness after etching than the etching by the CMP method). An explanation will be provided below about examples of the respective processes regarding the removal of the work-affected layer in the processing step according to the second embodiment. Incidentally, in this embodiment, etching other than the thermal etching process, the surface oxidation process, and the plasma etching process, for example, the etching by the CMP method may be performed or etching by other etching processes (such as hydrogen etching) may be performed.

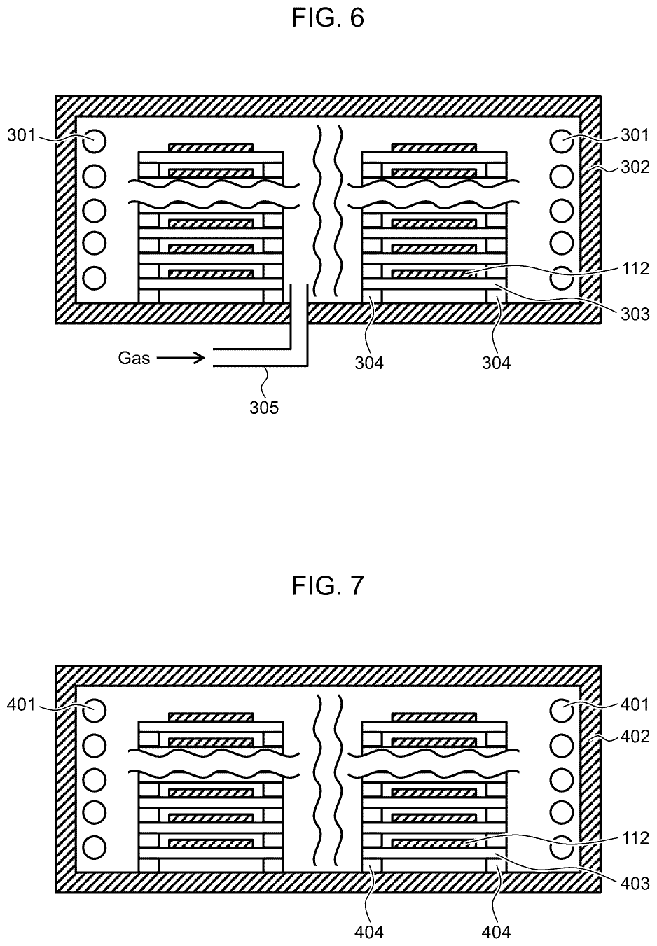

FIG. 6 schematically illustrates the thermal etching process.

The processing device 172 may include a device for removing the work-affected layer by the thermal etching process. The above-described device is a device illustrated as an example in FIG. 6. In the thermal etching process, about several μm of the surface of the remaining wafer (including the work-affected layer) heated and processed at an electric furnace 302 is sublimated.

For example, a gas (for example, an inert gas such as nitrogen or argon) is introduced via a gas pipe 305 into the electric furnace 302 which is composed of an insulation material and is provided with a heater 301, so that the inside of the electric furnace 302 becomes an inert gas atmosphere. The inside of the electric furnace 302 may be set as a vacuum atmosphere.

Heating is performed by the heater 301 and the highest heat treatment temperature is a temperature within a certain temperature range (for example, the range from 1000° C. to 2000° C.) and a temperature in consideration of a required etching amount may be set (for example, 1800° C. may be set). Moreover, the highest temperature keeping time is an amount of time within a certain time range (for example, from one minute to 5 hours) and the amount of time in consideration of the required etching amount may be set (for example, one hour may be set). The “required etching amount,” the “highest heat treatment temperature,” and the “highest temperature keeping time” may respectively be examples of at least one element of the grinding amount and may be decided based on the measured thickness of the work-affected layer.

The remaining wafer(s) 112 (for example, the remaining wafer 112 whose surface is ground) may be placed on a setter 303 (such as graphite) on spacers 304 (such as graphite) or may be located by using, for example, a pod composed of a heat-resistant material.

If the surface of the remaining wafer 112 is carbonized after this thermal etching process, the carbonized layer on the surface may be removed by separately performing annealing by an atmospheric atmosphere furnace or the like, or the carbonized layer on the surface may be removed by processing such as polishing. A carbon getter material such as Ta may be placed within the electric furnace 302 in order to prevent the carbonization of the surface.

FIG. 7 schematically illustrates the surface oxidation process.

The processing device 172 may include a device for removing the work-affected layer by the surface oxidation process. The above-described device is a device illustrated as an example in FIG. 7. In the surface oxidation process, the surface of the remaining wafer (including the work-affected layer) which is heated and processed at an electric furnace 402 in an oxidative atmosphere (including an atmospheric atmosphere) is oxidized to the thickness of about several μm. An oxidized film may be removed by processing such as polishing or may be caused to volatilize or melt (reaction with the base power) upon the crystal growth.

For example, at the electric furnace 402 which is composed of an insulation material and is provided with a heater 401, the highest heat treatment temperature is a temperature within a certain temperature range (for example, the range from 800° C. to 2000° C.) and a temperature in consideration of a required etching amount may be set (for example, 1400° C. may be set). Moreover, the highest temperature keeping time is an amount of time within a certain time range (for example, from 5 minutes to 50 hours) and the amount of time in consideration of the required etching amount may be set (for example, one hour may be set). The “required etching amount,” the “highest heat treatment temperature,” and the “highest temperature keeping time” may respectively be examples of at least one element of the grinding amount and may be decided based on the measured thickness of the work-affected layer.

The remaining wafer(s) 112 (for example, the remaining wafer 112 whose surface is ground) may be placed on a setter 403 (such as alumina) on spacers 404 (such as alumina).

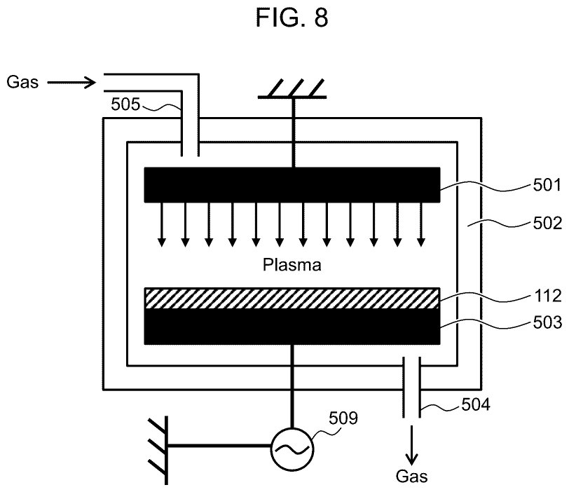

FIG. 8 schematically illustrates the plasma etching process.

The processing device 172 may include a device for removing the work-affected layer by the plasma etching process. The above-described device is a device illustrated as an example in FIG. 8. In the plasma etching process, about several μm of the processed surface of the remaining wafer (including the work-affected layer) undergoes the etching processing.

Examples of the plasma etching include RIE (Reactive Ion Etching), ECR (Electron Cyclotron Resonance), ICP (Inductively Coupled Plasma), CCP (Capacitively Coupled Plasma), etc.; however, there is no limitation and, for example, the RIE can be applied.

A substrate temperature, a gas type, treatment time, and a device configuration may be set as appropriate according to a desired etching rate and a surface state. Regarding the remaining wafer surface, deposits or the like on the surface may be removed in advance by, for example, ashing.

There are an upper electrode 501 and a lower electrode 503 within a chamber 502, a gas is introduced from a gas introduction pipe 505, the gas is caused to exit from a gas exhaust pipe 504, and plasma is generated between the electrodes 501 and 503 by a high-frequency power source 509.

The examples of the respective processes regarding the removal of the work-affected layer in the processing step according to the second embodiment have been explained above. Incidentally, regarding the crystal growth, for example, there are also differences described below between the sublimation method, the CVD method, and the NGK method.

Specifically speaking, the sublimation method and the CVD method require precision cleaning after the Chemical Mechanical Polishing (CMP) and before the formation of an epitaxial layer, while the NGK method does not require such cleaning.

Moreover, heating rates of the sublimation method and the CVD method are fast, thereby increasing the possibility that warpage of the seed crystal may damage the seed crystal. Furthermore, regarding the sublimation method and the CVD method, a plurality of seed crystals can be put in the chamber of the growth device; however, if even only one seed crystal is damaged, that will affect other seed crystals. On the other hand, regarding the NGK method, its heating rate is slower than that of the sublimation method or the CVD method, so that even if the seed crystal has some warpage, there is a low possibility that such warpage may cause damage. Furthermore, in the case of the NGK, one seed crystal is placed in one container, so that even if the seed crystal is damaged, that will not affect other seed crystals.

Furthermore, in either the second embodiment or the first embodiment, the diameter of the remaining wafer 112 acquired by the acquisition step may be 6 inches or more and, for example, the diameter of the remaining wafer may also be 8 inches or more (for example, in the second embodiment). For example, when the diameter is either 6 inches or 8 inches, the thickness of the main wafer 111 may be approximately 100 μm; however, if the diameter is 6 inches, the thickness of the remaining wafer 112 may be approximately 250 μm; and if the diameter is 8 inches, the thickness of the remaining wafer 112 may be approximately 400 μm.

According to the above-described embodiments of the present invention, the following operational advantages are obtained.
(1) The SiC wafer 40 is a semiconductor wafer of a disk shape containing SiC as a main component, has the seed crystal 114 made of the single crystal material of SiC (the first crystal layer) and the grown SiC crystals 115 made of a crystal layer of Sic formed on the seed crystal 114 (the second crystal layer), and the diameter of the disk shape is 145 mm or more. The release-promoting layer 116 is formed on at least one of the seed crystal 114 and the grown SiC crystals 115. The release-promoting layer 116 includes voids formed by the grooves 202 or the release-promoting substance which is the fine particles 211 or the ions 221. The grown SiC crystals 115 have a part containing nitrogen atoms at the concentration of 1×10¹⁸ atoms/cm³ or more. Consequently, it is possible to provide the SiC wafer 40 which can be easily divided at the release-promoting layer 116.
(2) Regarding the grown SiC crystals 115, the concentration of the nitrogen atoms at the depth of 25 μm from the first main surface 40a in the thickness direction perpendicular to the first main surface 40a should preferably be 1×10¹⁸ atoms/cm³ or more (Examples 1 to 5 and 8). More specifically, it is preferable that the grown SiC crystals 115 should have the thickness of at least 55 μm or more and the concentration of the nitrogen atoms at the depth of 55 μm from the first main surface 40a in the thickness direction perpendicular to the first main surface 40a should be 1×10¹⁸ atoms/cm³ or more. Moreover, the grown SiC crystals 115 should preferably have a part including a rare earth element(s) at the concentration of 5×10¹³ atoms/cm³ or more (Examples 1 to 4 and 8 to 10). Consequently, it is possible to improve the release performance at the release-promoting layer 116 and prevent the occurrence of breaking or cracking while performing the wafer division step.
(3) The SiC wafer 40 has the first main surface 40a and the second main surface 40b opposite the first main surface 40a. The release-promoting layer 116 is formed between the first main surface 40a and the second main surface 40b within the range of 10 μm or less in the thickness direction perpendicular to the first main surface 40a and the second main surface 40b. The release-promoting layer 116 is the area where voids formed by the grooves 202 or the release-promoting substance which is the fine particles 211 or the ions 221 are distributed at the interval of 200 μm or less throughout the range of 500 μm or more in the plane direction in parallel with the first main surface 40a and the second main surface 40b. Consequently, it is possible to provide the SiC wafer 40 which can be easily divided at the release-promoting layer 116.
(4) A method for manufacturing the SiC wafer 40 which is a semiconductor wafer of a disk shape containing SiC as a main component includes: a step of forming the obstruction area which obstructs the SiC crystal structure on a surface of, or in the vicinity of, the seed crystal 113a, 113b made of the SiC single crystal material (the pretreatment step); and a step of causing SiC crystals to grow with the thickness of 50 μm or more on a surface of the pretreated seed crystal 114 which is the SiC single crystal material, on which the pretreatment step has been performed, in a mixed gas atmosphere of argon and nitrogen (the growth step). Consequently, it is possible to manufacture the SiC wafer 40 which has the release-promoting layer 116 inside and which can be easily divided at the release-promoting layer 116.

Incidentally, the aforementioned embodiments have described the example where the remaining wafer 112 generated by the second entity is collected by the first entity and this remaining wafer 112 is used by the first entity to reclaim the SiC wafer 40; however, the present invention can be also applied in other aspects besides this. Specifically speaking, the present invention can be applied by a method similar to the aforementioned embodiments even when the first entity does not collect the remaining wafer 112, but manufactures the SiC wafer 40 by using only the seed crystal 113b which is made of a newly prepared SiC single crystal material.

An embodiment has been described above; however, this is merely an illustrative example to explain the present invention and there is no intention to limit the scope of the present invention to this embodiment. Furthermore, the present invention can be also executed in other various forms. For example, two or more arbitrary embodiments from among the aforementioned embodiments may be combined together.

What is claimed is:

1. A semiconductor wafer of a disk shape containing SiC as a main component, the semiconductor wafer comprising:
a first crystal layer made of a single crystal material of the SiC; and
a second crystal layer made of a crystal layer of the SiC formed on the first crystal layer,
wherein a diameter of the disk shape is 145 mm or more;
wherein a release-promoting layer is formed on at least one of the first crystal layer and the second crystal layer;
wherein the release-promoting layer includes voids or a release-promoting substance; and
wherein the second crystal layer has a part including nitrogen atoms at concentration of 1×10¹⁸ atoms/cm³ or more.

2. The semiconductor wafer according to claim 1,
wherein the second crystal layer has the concentration of the nitrogen atoms at a depth of 25 μm from a main surface in a thickness direction perpendicular to the main surface is 1×10¹⁸ atoms/cm³ or more.

3. The semiconductor wafer according to claim 1,
wherein the second crystal layer has the concentration of the nitrogen atoms at a depth of 55 μm from a main surface in a thickness direction perpendicular to the main surface is 1×10¹⁸ atoms/cm³ or more.

4. The semiconductor wafer according to claim 1,
wherein the second crystal layer has a part including rare earth elements at concentration of 5×10¹³ atoms/cm³ or more.

5. The semiconductor wafer according to claim 1, comprising:
a first main surface; and
a second main surface opposite the first main surface,
wherein the release-promoting layer is formed between the first main surface and the second main surface within a range of 10 μm or less in a thickness direction perpendicular to the first main surface and the second main surface; and
wherein the release-promoting layer is an area in which the voids or the release-promoting substance is distributed at an interval of 200 μm or less throughout a range of 500 μm or more in a plane direction in parallel with the first main surface and the second main surface.

6. The semiconductor wafer according to claim 1,
wherein the release-promoting substance is fine particles including carbon as a main component.

7. The semiconductor wafer according to claim 1,
wherein the release-promoting substance is ions of any one or more types of Si, C, Al, B, P, N, O, H, noble gas elements, and rare earth elements.

8. A method for manufacturing a semiconductor wafer of a disk shape containing SiC as a main component, the semiconductor wafer manufacturing method comprising:
a first step of forming an obstruction area which partially breaks or obstructs a SiC crystal structure on a surface of, or in vicinity of, a SiC single crystal material; and
a second step of causing SiC crystals to grow with a thickness of 50 μm or more on the surface of the SiC single crystal material, on which the first step has been performed, in a mixed gas atmosphere of argon and nitrogen.

9. The semiconductor wafer manufacturing method according to claim 8,
wherein in the first step, a plurality of grooves with a maximum depth of 1 μm or more are formed, as the obstruction area, in the surface of the SiC single crystal material.

10. The semiconductor wafer manufacturing method according to claim 8,
wherein in the first step, an area in which fine particles of graphite or diamond with a particle size of 10 μm or less are dispersed and placed is formed, as the obstruction area, on the surface of the SiC single crystal material.

11. The semiconductor wafer manufacturing method according to claim 8,
wherein in the first step, the obstruction area is formed by injecting ions of any one or more types of Si, C, Al, B, P, N, O, H, noble gas elements, and rare earth elements into the SiC single crystal material through its surface.

12. The semiconductor wafer manufacturing method according to claim 8,
comprising a third step of dividing the SiC single crystal material, on which the grown SiC crystals have been formed in the second step, into a main wafer including a surface of the grown SiC crystals and a remaining wafer excluding the main wafer.

13. The semiconductor wafer manufacturing method according to claim 12,
wherein a release-promoting layer composed of the obstruction area is formed inside the SiC single crystal material with the grown SiC crystals formed thereon; and
wherein in the third step, a modified layer is formed by applying a laser light to the release-promoting layer and the SiC single crystal material is divided, at the modified layer as a starting point, into the main wafer and the remaining wafer.

14. The semiconductor wafer manufacturing method according to claim 12,
wherein a release-promoting layer composed of the obstruction area is formed inside the SiC single crystal material with the grown SiC crystals formed thereon; and
wherein in the third step, the release-promoting layer is removed by etching and the SiC single crystal material is divided into the main wafer and the remaining wafer.
